(19) United States
(12) Patent Application Publication
(10) Pub. No.: US 2022/0020882 A1
(43) Pub. Date: Jan. 20, 2022

(54) STRUCTURE FOR A FIELD EFFECT TRANSISTOR (FET) DEVICE AND METHOD OF PROCESSING A FET DEVICE

(71) Applicant: IMEC vzw, Leuven (BE)

(72) Inventors: Nouredine Rassoul, Braine I'Alleud (BE); Romain Delhougne, Boortmeerbeek (BE); Attilio Belmonte, Schaerbeek (BE); Gouri Sankar Kar, Leuven (BE)

(21) Appl. No.: 17/305,797

(22) Filed: Jul. 14, 2021

(30) Foreign Application Priority Data
Jul. 15, 2020 (EP) 20185877.6

(51) Int. Cl. H01L 29/786; H01L 29/66; H01L 23/00; H01L 29/24; H01L 29/10

(52) U.S. Cl. CPC H01L 29/7869; H01L 29/66969; H01L 29/1083; H01L 29/24; H01L 23/564

(57) ABSTRACT

The disclosed technology generally relates to a structure for a field effect transistor (FET) device and a method of processing a FET device. In one aspect, the method can include providing a substrate, forming an oxygen passing layer on the substrate, and forming an oxygen blocking layer on the substrate. The oxygen blocking layer can be arranged next to the oxygen passing layer and can delimit the oxygen passing layer on two opposite sides. The method can also include forming an oxide semiconductor layer on the oxygen passing layer and the oxygen blocking layer, forming a gate structure on the oxide semiconductor layer in a region above the oxygen passing layer, and modifying a doping of the oxide semiconductor layer by introducing oxygen into the oxygen passing layer. At least a portion of the introduced oxygen can pass through the oxygen passing layer and into the oxide semiconductor layer.

### CROSS-REFERENCE TO RELATED APPLICATIONS

This application claims foreign priority to European Patent Application No. EP 20185877.6, filed Jul. 15, 2020, the content of which is incorporated by reference herein in its entirety.

### BACKGROUND

### Technical Field

The disclosed technology generally relates to a method of processing a field effect transistor (FET) device and to a structure for a FET device.

### Description of the Related Technology

Field effect transistors (FETs) are key electronic components in various electronic devices. Generally, a FET can comprise a channel that is arranged between a source and a drain contact, as well as a gate contact that is arranged in close proximity to the channel. An electric field can be applied to the gate contact to control a current flow through the channel. Thin-film-transistors (TFTs) are special types of FETs that can be made by depositing thin films, usually semiconductor layers, dielectric layers and metallic contacts, on non-conducting substrates.

Many modern applications, such as high-density memories, display-on-glass devices, or smart nano-interconnects, comprise such FETs. These devices often operate on a limited power budget and, thus, a better managing of electric power at the circuit and the FET level is desirable.

### SUMMARY OF CERTAIN INVENTIVE ASPECTS

It is an objective to provide an improved method of processing a FET device, and to provide an improved structure for a FET device.

The objective can be achieved by the embodiments provided in the enclosed independent claims. Advantageous implementations of the embodiments of the disclosed technology are further defined in the dependent claims.

According to one aspect, the disclosed technology relates to a method of processing a field effect transistor (FET) device, wherein the method can comprise:
providing a substrate;
forming an oxygen passing layer on the substrate;
forming an oxygen blocking layer on the substrate, wherein the oxygen blocking layer is arranged next to the oxygen passing layer and delimits the oxygen passing layer on two opposite sides;
forming an oxide semiconductor layer on the oxygen passing layer and the oxygen blocking layer;
forming a gate structure on the oxide semiconductor layer in a region above the oxygen passing layer; and
modifying a doping of the oxide semiconductor layer by introducing oxygen into the oxygen passing layer, wherein at least a portion of the introduced oxygen passes through the oxygen passing layer and into the oxide semiconductor layer.

In some implementations, a method of processing a FET device is provided which can efficiently control the electrical properties of the FET, for example, its oxide semiconductor channel layer. For example, at least some of the damage or defects in the channel layer that are, for instance, introduced during fabrication of the device and that change the doping of the layer in an unwanted way can be removed, and a desired concentration of oxygen dopants in the layer can be recovered. In various implementations, this repair of the oxide semiconductor channel layer can be carried out after depositing other layers or structures, such as the gate structure or a top gate isolator, on top of the oxide semiconductor layer.

In some instances, the oxygen blocking layer can confine the sections of the oxide semiconductor layer to which the oxygen is introduced. This can reduce and/or prevent the oxygen degrading contact resistances between the oxide semiconductor layer and other structures of the FET device, e.g., source and drain structures.

The substrate can be a glass or a silicon substrate. In some implementations, the substrate is a wafer.

The gate structure can comprise a gate dielectric layer that is formed above the oxide semiconductor layer. Several top gate dielectric materials, thicknesses and crystallinities can be used. Possible top gate materials are aluminum oxide (Al₂O₃), hafnium dioxide (HfO₂), or wide band gap oxide semiconductors, such as gallium zinc oxide (GZO) or silicon dioxide (SiO₂). The gate structure can further comprise an electric contact.

Optionally, a bottom gate can be formed on the substrate prior to forming the oxygen passing and the oxygen blocking layer. If such a bottom gate is formed on the substrate, the oxygen passing layer can act as a bottom gate dielectric of the FET device. The bottom gate can be formed as a material layer (e.g., uniform material layer in some instances) below the oxygen passing and the oxygen blocking layer, or it can be confined to a region below the oxygen passing layer. If the bottom gate is formed, the gate structure on the oxide semiconductor layer can be partially omitted, e.g., in some instances, only a gate oxide of the gate structure may be formed as a protective layer.

In some implementations, the FET device is a metal-oxide-semiconductor field-effect transistor (MOSFET). The FET device can be a planar transistor, in particular a thin-film transistor (TFT), or another type of transistor, such as a fin field effect transistor (FinFET).

In some implementations, the method can further comprise:
forming a source structure on the oxide semiconductor layer in a region above the oxygen blocking layer on one of the two opposite sides of the oxygen blocking layer; and
forming a drain structure on the oxide semiconductor layer in a region above the oxygen blocking layer on the other one of the two opposite sides of the oxygen blocking layer.

Advantageously, in some embodiments, the oxygen blocking layer below the source and drain structures can reduce and/or prevent a degradation of a contact resistance between the oxide semiconductor layer and the source and drain structures. Such a degradation could be caused by the introduced oxygen.

In some embodiments, at least the portion of the oxide semiconductor layer that is arranged between the oxygen passing layer and the gate structure can form a channel of the FET device.

Advantageously, a channel of the FET device with well controlled electrical properties, e.g., conductivity, can be provided in some embodiments.

In various implementations, the oxide semiconductor layer forming the channel can be made from a metal oxide semiconductor material.

In some embodiments, the doping of the oxide semiconductor layer can be modified in a section above the oxygen passing layer, wherein the section is essentially congruent (e.g., substantially congruent) or coextensive with the oxygen passing layer or wherein the section extends beyond the oxygen passing layer.

Advantageously, in some embodiments, the section of the oxide semiconductor layer where the doping is modified can be defined by the size of the oxygen passing layer.

In some embodiments, the oxygen can be introduced into the oxygen passing layer by oxygen annealing or annealing in the presence of oxygen, e.g., after forming the gate structure.

Advantageously, in some embodiments, the oxygen can be introduced in the oxygen passing layer in a simple and efficient way.

In various implementations, the oxygen annealing and, thus, the recovery of the oxide semiconductor layer can be performed at any stage of the full process flow, e.g., at the end of the process flow in some instances.

In some embodiments, a portion of the oxygen passing layer may not be covered by the gate structure.

Advantageously, in some embodiments, the oxygen can efficiently be introduced into the oxygen passing layer, after forming the gate structure on top of the oxide semiconductor layer. For example, the oxygen can penetrate the oxygen passing in the portion that is not covered, e.g., exposed, and, in some instances, distribute (e.g., evenly in some instances) throughout the oxygen passing layer and penetrate (e.g., evenly in some instances) into the oxide semiconductor layer above the passing layer.

In various implementations, the portion of the oxygen passing layer may also not be covered by a top gate isolator of the gate structure. In some instances, the oxygen passing layer may remain exposed after forming the FET device.

In some embodiments, the oxide semiconductor layer can comprise any one or more of the following materials: indium gallium zinc oxide (IGZO), indium tin oxide (ITO), or indium zinc oxide (IZO).

In some embodiments, the oxygen passing layer can comprise a silicon oxide layer, a silicon oxynitride layer, a porous material layer, and/or an air gap.

The air gap can be a gap between the oxide semiconductor layer and the substrate.

In some embodiments, the oxygen blocking layer can comprise a metallic and/or a dielectric material, for example tungsten nitride, silicon nitride, aluminum oxide, titanium, titanium nitride, ruthenium, hafnium dioxide, molybdenum, titanium tungsten, silver, gold, and/or silicon carbonitride.

In various implementations, a FET device processed with a method described herein can show “fingerprints” of that method. For example, the oxygen passing and blocking layers can be arranged below the channel and the source and drain structures of the FET device. In case the oxygen passing layer comprises a portion that is not covered by the gate structure, then this portion can also be visible in the processed FET device.

According to another aspect, the disclosed technology relates to a structure for a FET device, wherein the structure can comprise:
a substrate;
an oxygen passing layer arranged on the substrate;
an oxygen blocking layer arranged on the substrate, wherein the oxygen blocking layer is arranged next to the oxygen passing layer and delimits the oxygen passing layer on two opposite sides;
an oxide semiconductor layer arranged on the oxygen passing layer and the oxygen blocking layer; and
a gate structure arranged on the oxide semiconductor layer in a region above the oxygen passing layer;
wherein the oxide semiconductor layer comprises a doping, wherein the doping, e.g., a concentration of dopants, is modified in a section above the oxygen passing layer.

Advantageously, in some implementations, a structure for a FET device can be provided whose electrical properties, e.g., the electrical properties of its oxide semiconductor channel layer, can efficiently be controlled. In various embodiments, at least some of the damage or defects in the oxide semiconductor layer that are, for instance, introduced during fabrication of the structure and that change the doping of the layer in an unwanted way can be removed, and a desired concentration of oxygen dopants in the layer can be recovered. In some instances, this repair of the oxide semiconductor layer can be carried out after depositing other layers or structures, such as the gate structure, on top of the oxide semiconductor layer.

In various implementations, the oxygen blocking layer can reduce and/or prevent the oxygen that is introduced in the oxygen passing layer and that degrades a contact resistance between the oxide semiconductor layer and other structures o the FET device, e.g., source and drain metal contacts.

The structure can form a portion or section of the FET device or can form the entire FET device. In some implementations, the FET device is a metal-oxide-semiconductor field-effect transistor (MOSFET). The FET device can be a planar transistor, in particular a thin-film transistor (TFT), or another type of transistor, such as a FinFET.

The structure can be integrated in an electric device, such as a display, a memory, a data processing unit, or an interconnect.

In some embodiments, the structure can further comprise:
a source structure arranged on the oxide semiconductor layer in a region above the oxygen blocking layer on one of the two opposite sides of the oxygen blocking layer; and
a drain structure arranged on the oxide semiconductor layer in a region above the oxygen blocking layer on the other one of the two opposite sides of the oxygen blocking layer.

Advantageously, in some embodiments, the oxygen blocking layer below the source and drain structures can reduce and/or prevent a degradation of a contact resistance between the oxide semiconductor layer and the source and drain structures. Such a degradation could be caused by the introduced oxygen.

In some embodiments, at least the portion of the oxide semiconductor layer that is arranged between the oxygen passing layer and the gate structure can form a channel of the FET device.

Advantageously, a channel of the FET device with well controlled electrical properties, e.g., conductivity and contact resistance to source/drain, can be provided in some embodiments.

In some embodiments, the section in which the doping is modified can be congruent (e.g., substantially congruent) with the oxygen passing layer or the section can extend beyond the oxygen passing layer.

Advantageously, in some embodiments, the section of the oxide semiconductor layer where the doping is modified can be defined by the size of the oxygen passing layer.

In some embodiments, the oxide semiconductor layer can comprise any one or more of the following materials: indium gallium zinc oxide (IGZO), indium tin oxide (ITO), or indium zinc oxide (IZO).

In some embodiments, the oxygen passing layer can comprise a silicon oxide layer, a silicon oxynitride layer, a porous material layer, and/or an air gap.

In some embodiments, the oxygen blocking layer can comprise a metallic and/or a dielectric material, for example tungsten nitride, silicon nitride, aluminum oxide, titanium, titanium nitride, ruthenium, hafnium dioxide, molybdenum, titanium tungsten, silver, gold, and/or silicon carbonitride.

The descriptions with regard to the methods of processing the FET device are correspondingly valid for the structures for the FET device.

### BRIEF DESCRIPTION OF THE DRAWINGS

The disclosed technology will be explained in the following descriptions together with the figures.

FIGS. 1a, 1b, 1c, and 1d show various intermediate structures of a method of processing a FET device according to some embodiments.

FIGS. 2a, 2b, 2c, and 2d show various intermediate structures of a method of forming an oxygen passing layer and an oxygen blocking layer according to some embodiments;

FIGS. 3a, 3b, 3c, and 3d show various intermediate structures of a method of forming an oxygen passing layer and an oxygen blocking layer according to some embodiments;

FIG. 4 shows a cross-sectional view of a structure for a FET device according to some embodiments;

FIGS. 5a and 5b show respectively, a perspective view and a top view of a structure for a FET device according to some embodiments; and

FIGS. 6a and 6b show cross section views of structures for a FET device according to some embodiments.

### DETAILED DESCRIPTION OF CERTAIN ILLUSTRATIVE EMBODIMENTS

Oxide semiconductor materials may be used for the channel layer of a FET. Indium gallium zinc oxide (InGaZnO or “IGZO”) is an oxide semiconductor material that can provide several advantages, especially compared to doped amorphous silicon, when used as a channel layer. These advantages include, among others, an ultra-low off-state leakage current and a high electron mobility. Further, IGZO can allow processing with a low thermal budget, e.g., at low temperatures, enabling a sequential integration with silicon-based transistors.

Without being bound to any theory, doping mechanisms for amorphous IGZO (a-IGZO) include off stoichiometry of oxygen ions and incorporation of hydrogen. For the first defect family, oxygen vacancies can act as n-type dopants and form shallow donor levels in the IGZO bandgap. Regarding the role of hydrogen, the lead model can be linked to the break of weakly-bonded oxygen atoms like in Zn—O by H and forming —OH ions.

However, it can be difficult to control the electrical properties of a channel layer of a FET and to avoid damage to the layer during the FET fabrication. In particular, it can be difficult to control the concentration of oxygen vacancies in an IGZO channel, especially because hydrogen-based chemistries are commonly used in deposition and patterning steps of a FET fabrication process subsequent to the formation the IGZO channel.

Moreover, because the channel of a FET, in particular of a TFT, can be generally covered by other structures, such as a metal gate or a top gate insulator, it can be difficult to repair a damaged channel layer, e.g., to recover generated defects in the layer, following the deposition of these other layers. The above-mentioned disadvantages can be reduced and/or avoided in various implementations described herein.

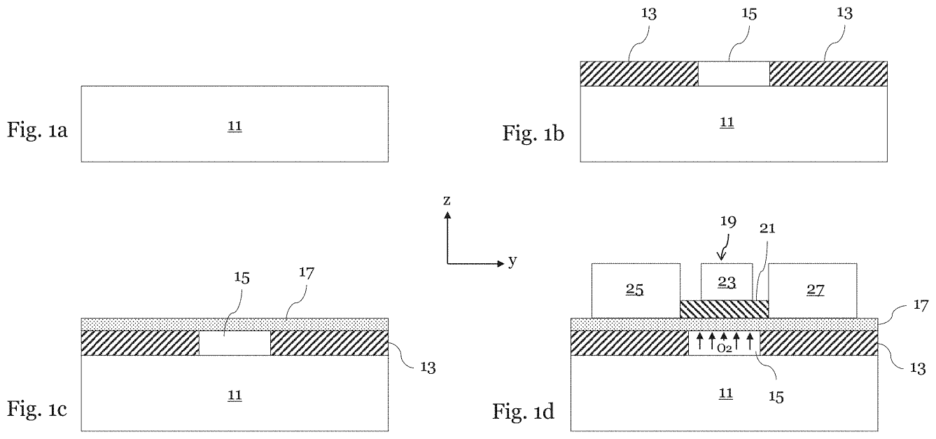

FIGS. 1a-1d show various intermediate structures of a method of processing a FET device according to some embodiments.

Thereby, FIGS. 1a-1d show the processing of a single FET device. Nevertheless, the method may be used to process a plurality of FET devices in parallel, e.g., on a common substrate 11.

The method can comprise, as shown in FIG. 1a, providing a substrate 11. The substrate 11 can be a glass or a silicon wafer. In some implementations, the substrate 11 can be a wafer, e.g., a 300 mm wafer.

As described herein, an oxygen passing layer refers to a layer which, when subjected to processing conditions suitable for oxide semiconductors as described herein, substantially diffuses oxygen atoms or ions therethrough. The amount of oxygen diffused through the oxygen passing layer can be comparable to or exceed a dopant concentration of a semiconductor channel. On the other hand, an oxygen blocking layer refers to a layer which, when subjected to processing conditions suitable for oxide semiconductors as described herein, substantially serves as a diffusion barrier to oxygen atoms or ions. The amount of oxygen diffused through the oxygen blocking layer can be less than a dopant concentration of a semiconductor channel. An oxygen blocking layer can diffuse substantially less oxygen atoms or ions, e.g., at least an order of magnitude less, relative to the oxygen passing layer.

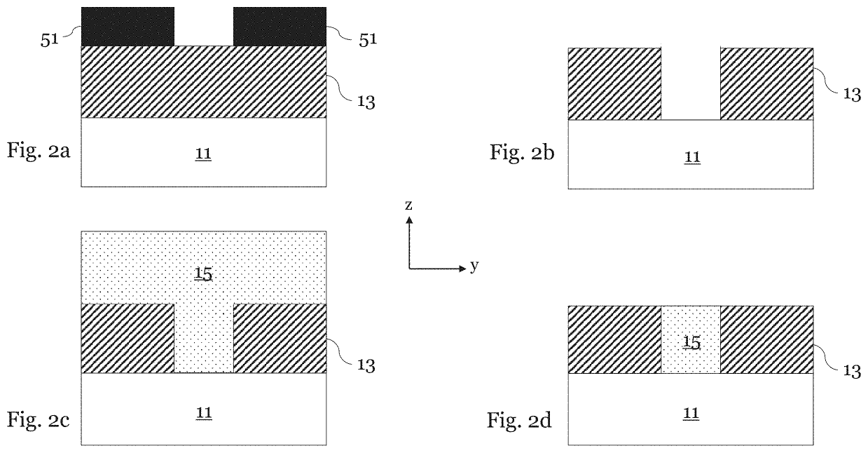

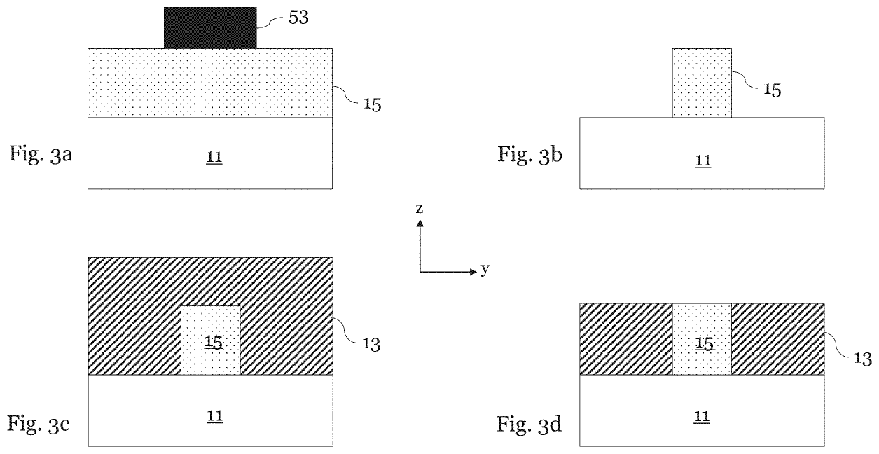

As shown in FIG. 1b, the method can comprise forming an oxygen passing layer 15 and an oxygen blocking layer 13 on the substrate 11. The oxygen blocking layer 13 can be arranged next to the oxygen passing layer 15 and can delimit the oxygen passing layer 15 on two opposite sides. Two methods of forming the oxygen passing layer 15 and the oxygen blocking layer 13 on the substrate 11 are shown in FIGS. 2a-2d and FIGS. 3a-3d and are discussed below.

In various implementations, the oxygen passing layer 15 can be a silicon oxide layer, e.g., a silicon dioxide layer. In some implementations, the oxygen passing layer 15 can be a porous material layer, e.g., a material having pores through which oxygen can propagate. The oxygen passing layer 15 can also form an air gap delimited by the oxygen blocking layer 13. The oxygen blocking layer 13 can be made of a metallic and/or a dielectric material, for example tungsten nitride, silicon nitride, aluminum oxide, titanium, titanium nitride, ruthenium, and/or hafnium dioxide.

The oxygen passing layer 15 and/or the oxygen blocking layer 13 can be deposited on the substrate 11 by a suitable deposition process, e.g., chemical vapor deposition.

Optionally, a bottom gate can be formed on the substrate 11 prior to forming the oxygen passing layer 15 and the oxygen blocking layer 13. If such a bottom gate is formed on the substrate, the oxygen passing layer 15 can act as a bottom gate dielectric of the FET device. The bottom gate can be formed as a material layer (e.g., a uniform material layer in some instances) below the oxygen passing layer 15 and the oxygen blocking layer 13, or it can be confined to a region below the oxygen passing layer 15.

As shown in FIG. 1c, an oxide semiconductor layer 17 can be formed on the oxygen passing layer 15 and the oxygen blocking layer 13.

The oxide semiconductor layer 17 can form a channel of the FET device. The oxide semiconductor layer 17 can be made from a metal oxide semiconductor material. In some instances, the oxide semiconductor layer 17 can be made from one or more of the following materials: indium gallium zin oxide (IGZO), indium tin oxide (ITO), and/or indium zinc oxide (IZO).

In some embodiments, the oxygen passing layer 15 can form an oxygen canal below the oxide semiconductor layer 17 through which oxygen (O₂) can diffuse.

As shown in FIG. 1d, the method can further comprise forming a gate structure 19 on the oxide semiconductor layer 17 in a region above the oxygen passing layer 15. For example, the gate structure 19 can comprise a gate oxide 21 and a gate metal contact 23. The gate oxide can be made of aluminum oxide (Al₂O₃) in some designs.

The method may further comprise forming a source structure 25 and a drain structure 27 on the oxide semiconductor layer 17 in regions above the oxygen blocking layer 13. For example, the source and drain structures 25, 27 can be formed on two opposite sides of the oxygen blocking layer. The oxide semiconductor layer 17 above the oxygen passing layer can form a FET channel between source and drain structures 25, 27.

However, several processing steps, for instance the formation of the source and drain structures 25, 27 can lead to damage and an unwanted doping (or change of a doping) of the oxide semiconductor layer 17. This unwanted doping can be caused by the formation of additional oxygen vacancies in the oxide semiconductor layer 17.

To recover the oxide semiconductor layer 17, oxygen can be introduced into the oxygen passing layer 15, wherein at least a portion of the introduced oxygen can pass through the oxygen passing layer 15 and into the oxide semiconductor layer 17 (indicated by arrows in FIG. 1d). Thereby, the doping of the oxide semiconductor layer 17 can be modified, e.g., by filling up at least some of the unwanted oxygen vacancies. In this context, modifying a doping of the oxide semiconductor layer 17 may refer to removing an unwanted doping from the layer 17 or restoring an initial doping of the layer 17, so that desired electrical properties of the layer 17 can be improved and/or restored.

The doping of the oxide semiconductor layer 17 can be modified in a section above the oxygen passing layer by the introduced oxygen atoms. In some implementations, the section can be congruent (e.g., substantially congruent) with the oxygen passing layer or can extend to a certain extent beyond the oxygen passing layer. In some instances, the oxygen atoms can diffuse for short distances within the oxide semiconductor layer 17, which may cause the size of the modified section to be larger, e.g., wider, than the oxygen passing layer 15 below. This effect can be taken into account when forming these layers 15, 17, such that modified section of the oxide semiconductor layer 17 can correspond to the channel of the FET device.

In various implementations, the oxygen blocking layer 13 below the source and drain structures 25, 27 can reduce and/or prevent a degradation of the contact and/or access resistance of the metal oxide semiconductor layer 17 to the source and drain structures 25, 27.

In some embodiments, the oxygen can be introduced into the oxygen passing layer 15 by oxygen annealing. The oxygen annealing can take place after forming the gate structure 19 and/or a top gate insolation layer on top of the oxide semiconductor layer 17.

In some embodiments, a portion of the oxygen passing layer 15 may not be covered by the gate structure 19. The oxygen passing layer 15 can extend along an x-direction, perpendicular to the cross-sectional view in y-z-direction as indicated by the schematic coordinate system in FIGS. 1a-1d. The portion of the oxygen passing layer 15 that is not covered by the gate structure 19 can be located in front or behind the gate structure 19 in x-direction. This uncovered or exposed portion of the oxygen passing layer 15 can improve the intake of oxygen atoms in some instances, e.g., during oxygen annealing, in the oxygen passing layer 15, e.g., because the metal gate or a top gate insulator can act as blocking layers for the oxygen. Once the oxygen atoms have entered the oxygen passing layer 15, they can spread through the layer 15 and into the oxide semiconductor layer 17 to realize recovery (e.g., a complete and uniform recovery in some instances) in the section above the passing layer 15.

FIGS. 2a-2d show intermediate structures of a method of forming the oxygen passing layer 15 and the oxygen blocking layer 13 on the substrate 11 according to some embodiments.

The method can comprise, as shown in FIG. 2a, forming the oxygen blocking layer 13 as a coating (e.g., a uniform coating in some instances) on the substrate 11 and forming a masking structure 51 on top of the oxygen blocking layer 13.

As shown in FIG. 2b, the oxygen blocking layer 13 can be selective removed below an opening of the masking structure 51, e.g., by dry or wet etching. As shown in FIG. 2c, the oxygen passing layer 15 material can be deposited on top of the structured oxygen blocking layer 13, e.g., into the recesses that was formed during the selective removal.

As shown in FIG. 2d, excess material of the oxygen passing layer 15 can be removed, e.g., by grinding or etching, such that the oxygen passing layer 15 can be confined to one or more recesses of the structured oxygen blocking layer 13.

FIGS. 3a-3d show intermediate structures of another method of forming the oxygen passing layer 15 and the oxygen blocking layer 13 on the substrate 11 according to some embodiments.

The method can start with forming the oxygen passing layer 15 as a coating (e.g., a uniform coating in some instances) on the substrate 11, as shown in FIG. 3a. A masking structure 53 can be formed on top of the oxygen passing layer 15. As shown in FIG. 3b, the oxygen passing layer 15 can be selective removed below openings of the masking structure 53.

As shown in FIG. 3c, the oxygen blocking layer 13 material can be deposited on top of the structured oxygen passing layer 15 and on the substrate 11 where the oxygen passing layer 15 was removed. As shown in FIG. 3d, excess material of the oxygen blocking layer 13 can be removed, e.g., by grinding or etching.

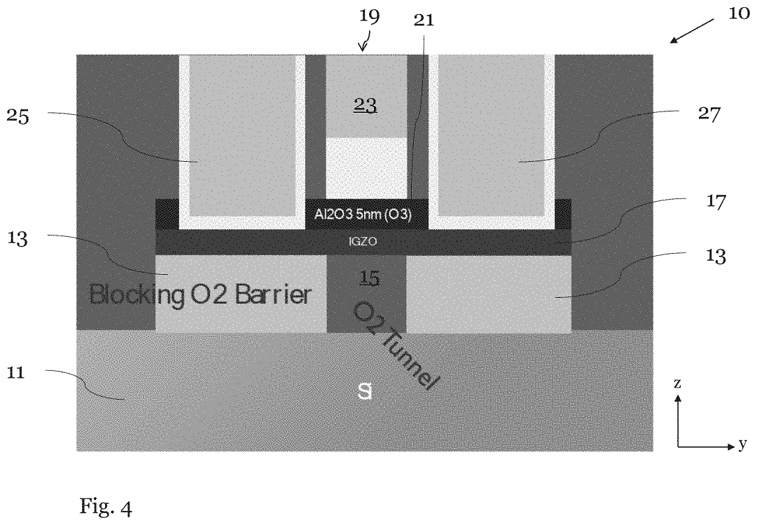

FIG. 4 shows a cross-sectional view of a structure 10 for the FET device according to some embodiments. The structure 10 shown in FIG. 4 can be processed by the method as shown in FIGS. 1a-1d.

The structure 10 can comprise the substrate 11 (e.g., Si), the oxygen passing layer 15 arranged on the substrate 11, and the oxygen blocking layer 13 arranged on the substrate 11, wherein the oxygen blocking layer 13 can be arranged next to the oxygen passing layer 15 and can delimit the oxygen passing layer 15 on two opposite sides. The structure 10 can further comprise the oxide semiconductor layer 17 (e.g., IGZO) arranged on the oxygen passing layer 15 and the oxygen blocking layer 13, and the gate structure 19 arranged on the oxide semiconductor layer 17 in a region above the oxygen passing layer 15, wherein the oxide semiconductor layer 17 can comprise a doping, wherein the doping, e.g., a concentration of dopants, can be modified in the section above the oxygen passing layer 17.

Modifying the doping in the section of the oxide semiconductor layer 17 can refer to removing unwanted dopants, e.g., oxygen vacancies, and/or restoring electrical properties of the oxide semiconductor layer 17 that have been changed during the FET processing.

In some embodiments, the portion, respective section, of the oxide semiconductor layer 17 that is arranged between the oxygen passing layer 15 and the gate structure 19, can form a channel of the FET device. The section of the oxide semiconductor layer 17 in which the doping is modified can correspond to the channel.

The modified section of the oxide semiconductor layer 17 can be congruent (e.g., substantially congruent) with the oxygen passing layer 15 or can extend beyond the oxygen passing layer 17.

The gate structure shown in FIG. 4 can comprise the gate oxide 21, which can be for instance an aluminum oxide (Al₂O₃) (e.g., 5 nm Al₂O₃), and the gate metal contact 21.

The structure 10 can form a portion or section of the FET device or can form the entire FET device. In some implementations, the FET device is a metal-oxide-semiconductor field-effect transistor (MOSFET). The FET device can be a planar transistor, in particular a thin-film transistor (TFT), or another type of transistor, such as a FinFET.

The structure 10 may further comprise a source structure 25 and a drain structure 27, which are arranged on the oxide semiconductor layer 17 in a region above the oxygen blocking layer 15.

In some embodiments, the oxide semiconductor layer 17 can comprise any one or more of the following materials: indium gallium zinc oxide (IGZO), indium tin oxide (ITO), or indium zinc oxide (IZO).

The oxygen passing layer may comprise a silicon oxide layer, a silicon oxynitride layer, a porous material layer, and/or an air gap. The oxygen passing layer 15 can form a channel or tunnel for oxygen atoms below the oxide semiconductor layer 17. The oxygen atoms can penetrate the oxide semiconductor layer 17 in a section above the oxygen passing layer 15 and, can change the concentration of dopants, e.g., oxygen vacancies, in the oxygen passing layer 15. In this way, damage in the oxide semiconductor layer 17 caused by fabrication steps of the FET processing can be repaired and an intended doping of the passing layers 17 can be restored.

The oxygen blocking layer or barrier may comprise a metallic and/or a dielectric material layer, for example tungsten nitride, silicon nitride, aluminum oxide, titanium, titanium nitride, ruthenium, and/or hafnium dioxide.

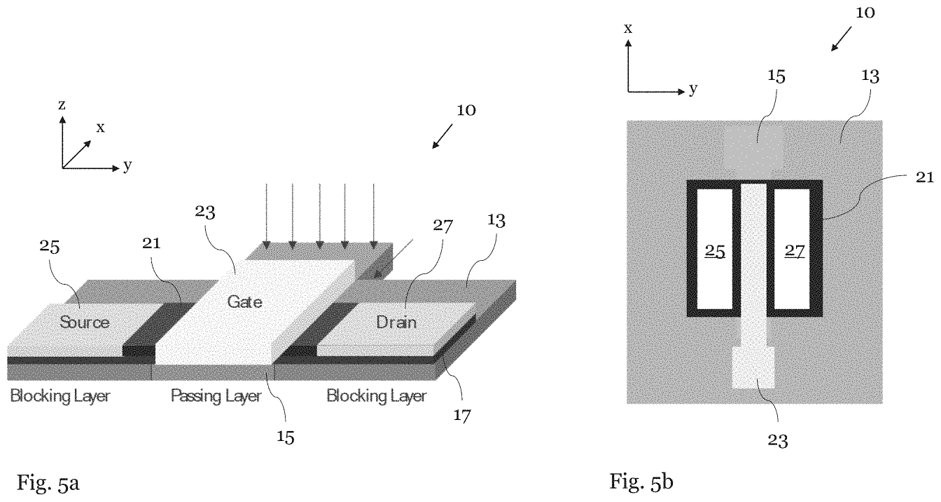

FIGS. 5a-5b show a perspective view and a top view of a structure 10 for a FET device according to some further embodiments. For example, the structures 10 shown in FIGS. 5a and 5b can correspond to the structure 10 shown in FIG. 4.

In the embodiments shown in FIGS. 5a and 5b, a portion of the oxygen passing layer 15 is not covered by the gate structure, which is formed by the gate oxide 21 and the gate metal contact 23.

As indicated by the arrows in FIG. 5a, oxygen can be introduced into this portion after forming the gate structure on top of the oxide semiconductor layer 17. For example, the oxygen can penetrate the oxygen passing 15 at this exposed portion and can distribute (e.g., evenly in some instances) throughout the oxygen passing layer and, e.g., below the oxide semiconductor layer 17.

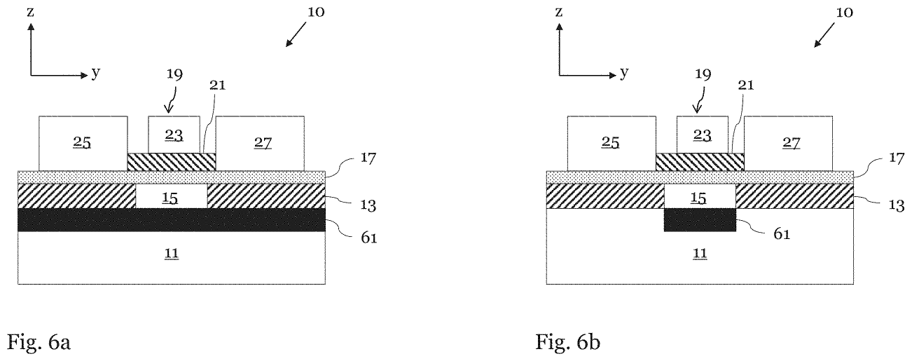

FIGS. 6a-6b show cross sectional views of two further embodiments of the structure 10 for the FET device. Both structures 10 shown in FIGS. 6a and 6b can comprise an additional bottom gate 61. Thereby, the oxygen passing layer 15 on top of the bottom gate 61 can act as a bottom gate dielectric layer. The bottom gate 61 can be a metallic layer on the substrate 11.

In the structure 10 depicted in FIG. 6a, the bottom gate 61 is arranged below the oxygen passing layer 15 and the oxygen blocking layer 13. This arrangement can make it easier to process the bottom gate, for example as a single material layer on the substrate 11 in some embodiments.

The blocking layer 13 can be made of a dielectric or non-conductive material, e.g., an oxide, or of a conductive material. If the blocking layer 13 is made of a dielectric or non-conductive material, the carriers can be injected into the channel from the bottom gate 61 via the oxygen passing layer 15. This carrier injection can lead to a boost of the on-current of the FET device. In some instances, no or only little injection takes place via the dielectric or non-conductive oxygen blocking layer 13. If, however, the blocking layer 13 is made of a conductive material, carriers can additionally be injected from the bottom gate 61 into the source and drain structures 25, 27 via the blocking layer 13. This can lead to an additional boost of the on-current of the FET device, wherein the bottom gate 61 can be used to control the current.

In the structure 10 depicted in FIG. 6b, the bottom gate 61 is confined to a region below the oxygen passing layer 15. This arrangement of the bottom gate 61 may include additional processing steps in some instances. Advantageously, in some such designs, the carrier injection from the bottom gate 61 can be confined to the oxygen passing layer 15. Hence, the conductivity of the oxygen blocking layer 13 may have less of an impact on the boost of the on-current.

Both structures 10 in FIGS. 6a and 6b can comprise a gate structure 19 above the channel. Leaving this top gate structure 19 intact can make the processing of the structures 10 more scalable in some embodiments.

In some implementations, the top gate structure 19, e.g., the gate metal contact 23, can be omitted when processing the respective structures 10, to generate structures that comprise the bottom gate 61 but no top gate. This may reduce the complexity of the processing of the structures 10 in some instances, since no patterning of the top gate structure 19 is performed. In some designs, the gate oxide 21 can be formed on the oxide semiconductor layer 17 to serve as a protective layer, and the gate metal contact 23 on top of this gate oxide 21 can be omitted.

While methods and processes may be depicted in the drawings and/or described in a particular order, it is to be recognized that the steps need not be performed in the particular order shown or in sequential order, or that all illustrated steps be performed, to achieve desirable results. Further, other steps that are not depicted may be incorporated in the example methods and processes that are schematically illustrated. For example, one or more additional steps may be performed before, after, simultaneously, or between any of the illustrated steps. Additionally, the steps may be rearranged or reordered in other embodiments.

In the above the inventive concept has mainly been described with reference to a limited number of examples. However, as is readily appreciated by a person skilled in the art, other examples than the ones disclosed above are equally possible within the scope of the inventive concept, as defined by the appended claims.

What is claimed is:

1. A method of processing a field effect transistor (FET) device, wherein the method comprises:
providing a substrate;
forming an oxygen passing layer on the substrate;
forming an oxygen blocking layer on the substrate, wherein the oxygen blocking layer is arranged next to the oxygen passing layer and delimits the oxygen passing layer on two opposite sides;
forming an oxide semiconductor layer on the oxygen passing layer and the oxygen blocking layer;
forming a gate structure on the oxide semiconductor layer in a region above the oxygen passing layer; and
modifying dopants of the oxide semiconductor layer by introducing oxygen into the oxygen passing layer, wherein at least a portion of the introduced oxygen passes through the oxygen passing layer and into the oxide semiconductor layer.

2. The method according to claim 1, further comprising:
forming a source structure on the oxide semiconductor layer in a region above the oxygen blocking layer on one of the two opposite sides of the oxygen blocking layer; and
forming a drain structure on the oxide semiconductor layer in a region above the oxygen blocking layer on the other of the two opposite sides of the oxygen blocking layer.

3. The method according to claim 1, wherein at least the portion of the oxide semiconductor layer that is arranged between the oxygen passing layer and the gate structure forms a channel of the FET device.

4. The method according to claim 1, wherein the dopants of the oxide semiconductor layer is modified in a section of the oxide semiconductor layer over the oxygen passing layer, wherein the section is substantially congruent with the oxygen passing layer or wherein the section extends beyond the oxygen passing layer.

5. The method according to claim 1, wherein the oxygen is introduced into the oxygen passing layer by annealing in oxygen.

6. The method according to claim 5, wherein the oxygen is introduced into the oxygen passing layer after forming the gate structure.

7. The method according to claim 1, wherein a portion of the oxygen passing layer is not covered by the gate structure.

8. The method according to claim 1, wherein the oxide semiconductor layer comprises one or more of the following materials: indium gallium zinc oxide, indium tin oxide, or indium zinc oxide.

9. The method according to claim 1, wherein the oxygen passing layer comprises a silicon oxide layer, a silicon oxynitride layer, a porous material layer, and/or an air gap.

10. The method according to claim 1, wherein the oxygen blocking layer comprises a metallic and/or a dielectric material.

11. The method according to claim 10, wherein the oxygen blocking layer comprises tungsten nitride, silicon nitride, aluminum oxide, titanium, titanium nitride, ruthenium, hafnium dioxide, molybdenum, titanium tungsten, silver, gold, and/or silicon carbonitride.

12. A structure for a field effect transistor (FET) device, wherein the structure comprises:
a substrate;
an oxygen passing layer arranged on the substrate;
an oxygen blocking layer arranged on the substrate, wherein the oxygen blocking layer is arranged next to the oxygen passing layer and delimits the oxygen passing layer on two opposite sides;
an oxide semiconductor layer arranged on the oxygen passing layer and the oxygen blocking layer; and
a gate structure arranged on the oxide semiconductor layer in a region above the oxygen passing layer;
wherein the oxide semiconductor layer comprises dopants, wherein the dopants are modified in a section of the oxide semiconductor layer over the oxygen passing layer.

13. The structure according to claim 12, wherein a concentration of the dopants is modified in the section of the oxide semiconductor layer over the oxygen passing layer.

14. The structure according to claim 12, further comprising:
a source structure arranged on the oxide semiconductor layer in a region above the oxygen blocking layer on one of the two opposite sides of the oxygen blocking layer; and
a drain structure arranged on the oxide semiconductor layer in a region above the oxygen blocking layer on the other of the two opposite sides of the oxygen blocking layer.

15. The structure according to claim 12, wherein at least the portion of the oxide semiconductor layer that is arranged between the oxygen passing layer and the gate structure forms a channel of the FET device.

16. The structure according to claim 12, wherein the section is substantially congruent with the oxygen passing layer or wherein the section extends beyond the oxygen passing layer.

17. The structure according to claim 12, wherein the oxide semiconductor layer comprises one or more of the following materials: indium gallium zinc oxide, indium tin oxide, or indium zinc oxide.

18. The structure according to claim 12, wherein the oxygen passing layer comprises a silicon oxide layer, a silicon oxynitride layer, a porous material layer, and/or an air gap.
